(19) United States
(12) Patent Application Publication
(10) Pub. No.: US 2026/0344463 A1
(43) Pub. Date: Oct. 29, 2026

(54) VIAS IN SEMICONDUCTOR PACKAGE

(71) Applicant: Taiwan Semiconductor Manufacturing Co., Ltd., Hsinchu (TW)

(72) Inventors: Yu-Huan Chen, Taoyuan City (TW); Kai-Yi Tang, New Taipei City (TW); Kuo-Ching Hsu, Chung-Ho City (TW)

(21) Appl. No.: 19/727,042

(22) Filed: Jul. 1, 2026

Related U.S. Application Data
(62) Division of application No. 18/240,065, filed on Aug. 30, 2023.

(51) Int. Cl. H10W 70/60; H10W 70/63; H10W 70/685; H10W 74/01; H10W 90/00

(52) U.S. Cl. CPC H10W 70/614; H10W 70/611; H10W 70/635; H10W 70/685; H10W 74/01; H10W 90/00

(57) ABSTRACT

A device is provided that includes a first semiconductor component embedded in a first core substrate, a first redistribution layer on a first side of the first core substrate, a second redistribution layer on a second side of the first core substrate opposite the first side, a first resin film over the second redistribution layer, a second semiconductor component embedded in a second core substrate, a third redistribution layer on a third side of the second core substrate, wherein the third redistribution layer is bonded to the second redistribution layer by the first resin film, a fourth redistribution layer on a fourth side of the second core substrate opposite the third side, and a through hole via extending through the first redistribution layer, the first core substrate, the second redistribution layer, the third redistribution layer, the second core substrate, and the fourth redistribution layer.

This application is a divisional of U.S. Patent Application No. 18/240,065, filed on Aug. 30, 2023, which application is hereby incorporated herein by reference.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Dozens or hundreds of integrated circuits are typically manufactured on a single semiconductor wafer. The individual dies are singulated by sawing the integrated circuits along scribe lines. The individual dies are then packaged separately, in multi-chip modules, or in other types of packaging.

The semiconductor industry has experienced rapid growth due to continuous improvement in the integration density of a variety of electronic components (e.g., transistors, diodes, resistors, capacitors, or the like). For the most part, this improvement in integration density has come from repeated reductions in minimum feature size, which allows more components to be integrated into a given area. As the demand for miniaturization, higher speed, and greater bandwidth, as well as lower power consumption and latency has grown recently, there has grown a need for smaller and more creative packaging techniques for semiconductor dies.

As semiconductor technologies further advance, stacked semiconductor devices, e.g., three dimensional integrated circuits (3DICs), have emerged as an effective alternative to further reduce the physical size of semiconductor devices. In a stacked semiconductor device, active circuits such as logic, memory, processor circuits, and the like are fabricated on different semiconductor wafers. Two or more semiconductor wafers may be installed or stacked on top of one another to further reduce the form factor of the semiconductor device. Package-on-package (POP) devices are one type of 3DICs where dies are packaged and are then packaged together with another packaged die or dies. Chip-on-package (COP) devices are another type of 3DICs where dies are packaged and are then packaged together with another die or dies.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 9 illustrate cross-sectional views of various steps in forming a first substrate layer in accordance with some embodiments.

FIGS. 10 through 13 illustrate cross-sectional views of various steps in forming a multi-core substrate in accordance with some embodiments.

FIGS. 14 through 16 illustrate cross-sectional views of various steps in forming second through hole vias in accordance with some embodiments.

FIGS. 17 through 19 illustrate cross-sectional views of various steps in forming redistribution structures over the multi-core substrate in accordance with some embodiments.

FIG. 20 illustrates a cross-sectional view of the attachment of the multi-core substrate to a package substrate and the attachment of a semiconductor device to the multi-core substrate in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature’s relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments discussed herein may be discussed in a specific context, namely a package component having one or more integrated circuit dies. In some embodiments, the package component is a system-on-integrated-substrate (SoIS) package. The package component includes an integrated substrate having multiple core substrates with embedded components within the core substrates. The core substrates are bonded to each other and can include redistribution structures. The integrated substrate having multiple core substrates allows for high-density integration of semiconductor components within the integrated substrate. The embedded semiconductor components within the multiple core substrates of the integrated substrate increase the communication bandwidth across the integrated substrate while maintaining low contact resistance and high reliability.

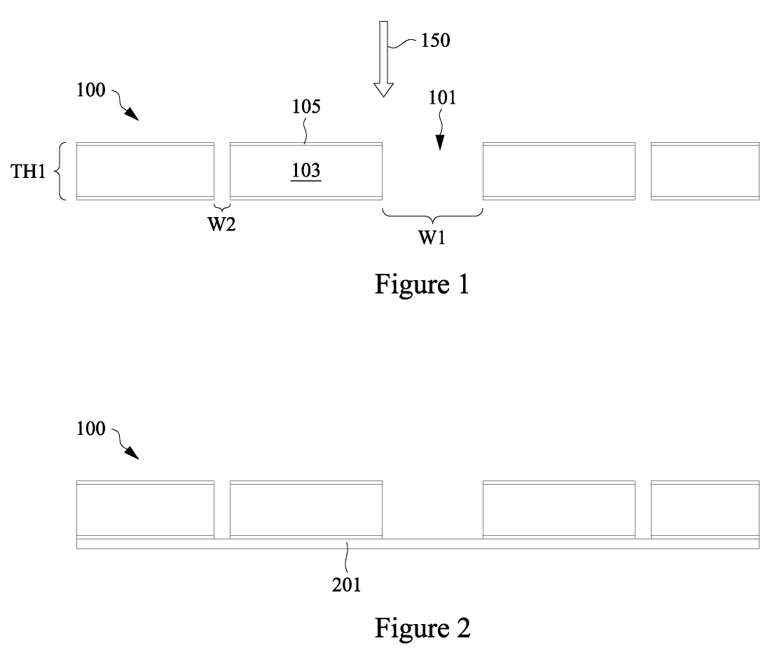

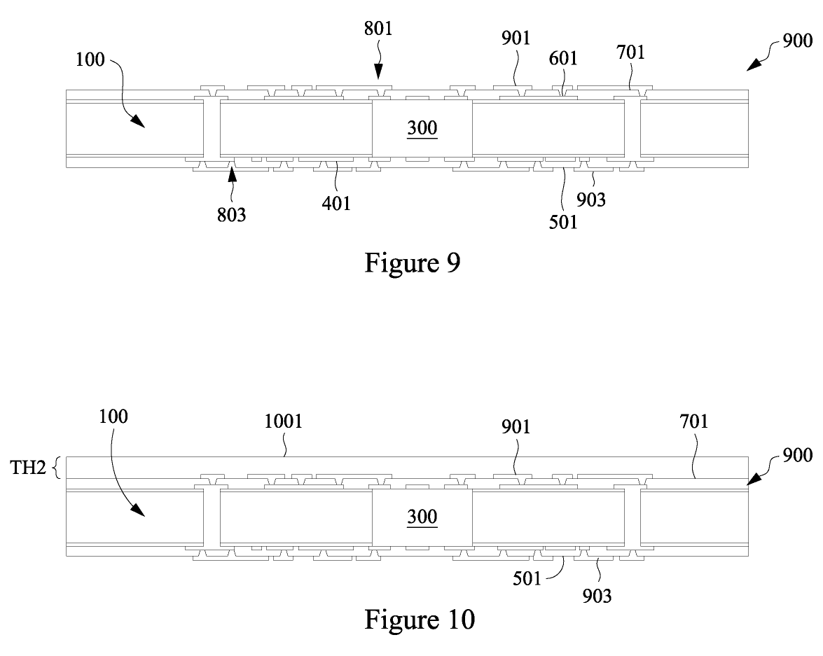

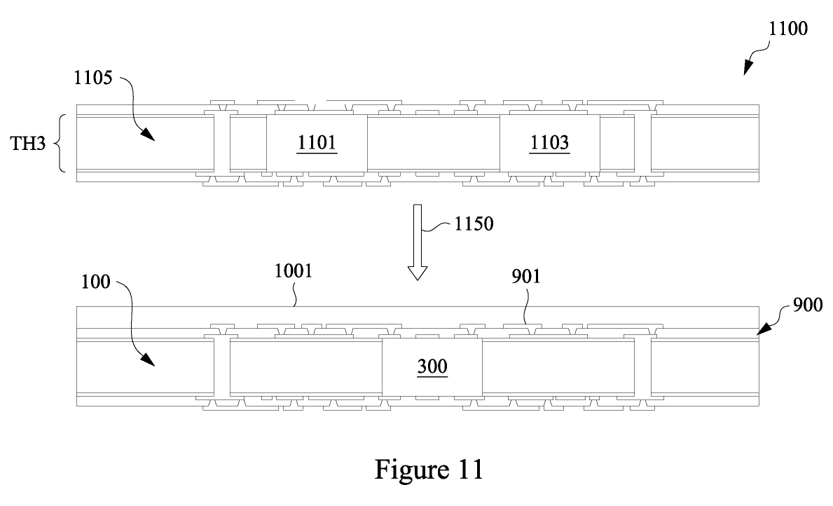

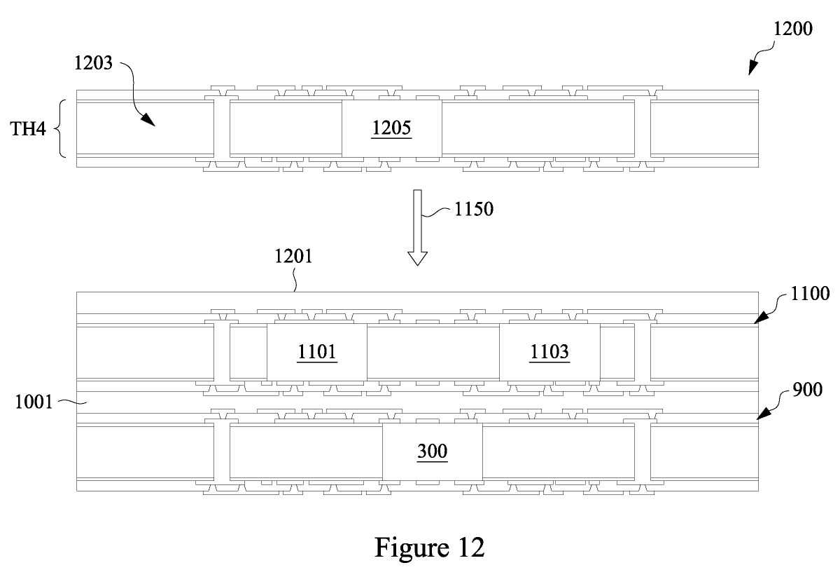

FIGS. 1 through 9 illustrate cross-sectional views of various steps in forming a first substrate layer 900 (see FIG. 9). In an embodiment, the first substrate layer 900 comprises embedding semiconductor components in a core substrate, forming through hole vias through the core substrate, forming dielectric layers on opposing sides of the core substrate, and forming metallization patterns on opposing sides of the core substrate. In an embodiment, the various steps in forming the first substrate layer 900 may be repeated to form a second substrate layer 1100 (see FIG. 11), a third substrate layer 1200 (see FIG. 12), and so on that may then be subsequently bonded.

FIG. 1 illustrates a cross-sectional view of a first core substrate 100 with first openings 101 in accordance with some embodiments. In some embodiments, the first core substrate 100 includes a first central core 103 with first conductive layers 105 on both sides of the first central core 103. In some embodiments, the first core substrate 100 is a double-sided copper-clad laminate (CCL) substrate. The first central core 103 may be an organic substrate, a ceramic substrate, a pre-impregnated composite fiber (prepreg), Ajinomoto Build-up Film (ABF), paper, glass fiber, non-woven glass fabric, other insulating materials, or combinations thereof. The first conductive layers 105 may be one or more layers of copper, nickel, aluminum, other conductive materials, or a combination thereof laminated or formed onto opposing sides of the first central core 103.

FIG. 1 further illustrates the formation of the first openings 101 in the first core substrate 100. In some embodiments, the first openings 101 are formed by laser drilling. Other processes, e.g., mechanical drilling, etching, or the like, may also be used. The first openings 101 may have a rectangular, circular, or other shape in a top-down view.

Following the formation of the first openings 101, a surface preparation process 150 may be performed. The surface preparation process 150 may include cleaning the exposed surfaces of the first core substrate 100 (e.g., surfaces of the first conductive layers 105 and surfaces of the first central core 103 in the first openings 101) with one or more cleaning solutions (e.g., sulfuric acid, chromic acid, neutralizing alkaline solution, water rinse, or the like) to remove or reduce soil, oils, and/or native oxide films. A desmear process may be performed to clean the area near the first openings 101, which may have been smeared with the material of the first central core 103 that was removed to form the first openings 101. The desmearing may be accomplished mechanically (e.g., blasting with a fine abrasive in a wet slurry), chemically (e.g., rinsing with a combination of organic solvents, permanganate or the like), or by a combination of mechanical and chemical desmearing. Following cleaning, treatment with a chemical conditioner, which facilitates adsorption of an activator used during subsequent electroless plating, may be used. In some embodiments, the conditioning step may be followed by micro-etching the first conductive layers 105 to micro-roughen the conductive surfaces of the first conductive layers 105 for better bonding between the first conductive layers 105 and later-deposited conductive material.

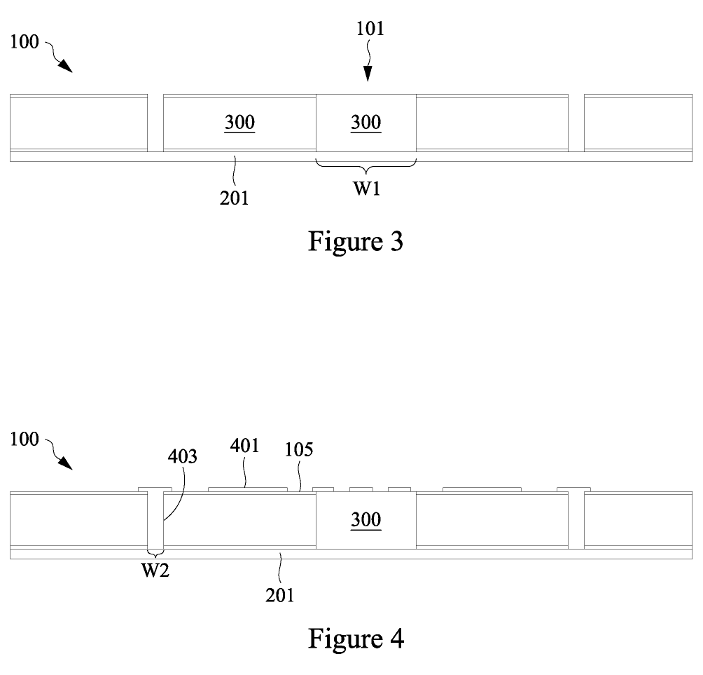

In accordance with some embodiments, the first core substrate 100 is formed to a first thickness TH1 to facilitate the embedding of semiconductor components within the first core substrate 100 (e.g., a first semiconductor component 300, see FIG. 3). The first thickness TH1 may be in a range of 50 µm to 1,400 µm. If the first core substrate 100 is formed to a thickness greater than the first thickness TH1, then too large of a gap may exist between the semiconductor components to be embedded within the first core substrate 100 and subsequently formed conductive features (e.g., first conductive traces 401, see FIG. 4). If the first core substrate 100 is formed to a thickness less than the first thickness TH1, then the first core substrate 100 may be too thin to accommodate the semiconductor component to be embedded within the first core substrate 100 and the semiconductor component may protrude too far outside the first core substrate 100 interfering with the formation of the subsequently formed conductive features (e.g., the first conductive traces 401, see FIG. 4). Further, in accordance with some embodiments, the first openings may be formed to multiple widths. One or more of the first openings 101 may be formed to a first width W1 to facilitate the embedding of the semiconductor components within the first core substrate 100 (e.g., the first semiconductor component 300, see FIG. 3). The first width W1 may be in a range of 50 µm to 500 µm larger than a width of the first semiconductor component 300. If the first width W1 exceeds 500 µm larger than the width of the first semiconductor component 300 than too large the semiconductor components may not be adequately secured within the first core substrate 100. If the first opening 101 is formed to a width less than the first width W1, then the first opening 101 may be too small to accommodate the semiconductor components to be embedded within the first core substrate 100 and the semiconductor components may be too small to fit within the first opening 101. Additionally, one or more of the first openings 101 may be formed to a second width W2 to facilitate formation of conductive material within the first openings 101 (e.g., a first through via 403, see FIG. 4). The second width W2 may be in a range of 50 µm to 1,400 µm. In an embodiment, the first openings 101 may be formed to the second width W2 to accommodate the formation of plating through hole vias (PTH) vias (e.g., the first through via 403) to connect metallization patterns on a front side to metallization patterns on a backside of the first core substrate 100.

FIG. 2 illustrates a cross-sectional view of attaching a film tape 201 to a first side of the first core substrate 100. The film tape 201 may be used to facilitate a placement of a semiconductor component (e.g., the first semiconductor component 300, see FIG. 3) within one of the first openings 101 that has first width W1. In an embodiment, the film tape 201 may be a polymer film, for example a polyimide film. The polyimide film may be used to provide structural support while providing adequate placement base for the semiconductor component to be embedded within the first opening 101 within the first core substrate 100. However, any suitable film tape 201 may be utilized, such as an ultraviolet tape which may lose its adhesive properties when exposed to ultra-violet light, pressure-sensitive tapes, radiation-curable tapes, combinations of these, or the like.

FIG. 3 illustrates a cross-sectional view of the first semiconductor component 300 embedded within the first core substrate 100 in one of the first openings 101 that has the first width W1. In accordance with some embodiments, the first semiconductor component 300 may be an active component, such as a transistor or the like. In some embodiments, the semiconductor component may be a passive component, such as a capacitor, an inductor, a resistor, the like, or a combination thereof. The first semiconductor component 300 may be a semiconductor die, an integrated passive device (IPD), an active chip, an integrated voltage regulator (IVR), a multilayer ceramic capacitor (MLCC), or the like. The first semiconductor component 300 may be embedded within one of the first openings 101 having the first width W1 by placing the first semiconductor component 300 in the first opening 101 having the first width W1 onto a surface of the film tape 201 exposed within the first opening 101. In some embodiments, the first semiconductor component 300 may be placed in the first opening 101 on the exposed surface of the film tape 201 using a pick and place process. However, any suitable process may be utilized to place the first semiconductor component 300 onto the exposed surface of the film tape 201 in the first opening 101. In some embodiments, once the first semiconductor component 300 has been placed within the first core substrate 100 the first semiconductor component 300 may be secured within the first opening 101 by a dielectric material.

FIG. 4 illustrates a cross-sectional view of the formation of a first through via 403 in the first core substrate 100. and of the first conductive traces 401 on an opposite side of the first core substrate 100 from the film tape 201. In an embodiment, the first openings 101 not occupied by the first semiconductor component 300 may be filled to form first through vias 403, and the first conductive traces 401 are formed over, the first through vias 403, the first core substrate 100, and the first semiconductor component 300 embedded therein on the opposite side of the first core substrate 100 from the film tape 201. In an embodiment, forming the first through vias 403 and the first conductive traces 401 may be formed by forming a seed layer (not separately illustrated) over the first core substrate 100. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, physical vapor deposition (PVD), CVD, or the like. A photoresist (not separately illustrated) is then formed and patterned on the seed layer. The photoresist may be formed by spin coating or the like, may be exposed to patterned light or another patterned energy source, and may be exposed to a developer to remove exposed or unexposed portions of the photoresist. The pattern of the photoresist corresponds to the first conductive traces 401. The patterning forms openings through the photoresist to expose the seed layer. A conductive material (not separately illustrated) is formed in the openings of the photoresist and on the exposed portions of the seed layer. The conductive material may be formed by plating, such as electroplating, electroless plating, or the like. The conductive material may comprise a metal, such as copper, titanium, tungsten, aluminum, or the like. The photoresist and portions of the seed layer on which the conductive material is not formed are then removed. The photoresist may be removed by an acceptable ashing or stripping process, such as using an oxygen plasma or the like. Once the photoresist is removed, exposed portions of the seed layer are removed using an acceptable etching process such as wet or dry etching. The remaining portions of the seed layer and the conductive material form the first through vias 403 and the first conductive traces 401.

After forming the first conductive traces 401 and the first through vias 403, the patterned mask layer (e.g., the photoresist) may be stripped. In some embodiments, portions of the first conductive layers 105 that were covered by the patterned mask layer may be removed using a suitable etching process. Removal of unwanted portions of the first conductive layers 105 prevents unwanted electrical shorts between the conductive features formed in the regions that were exposed by the patterned mask layer.

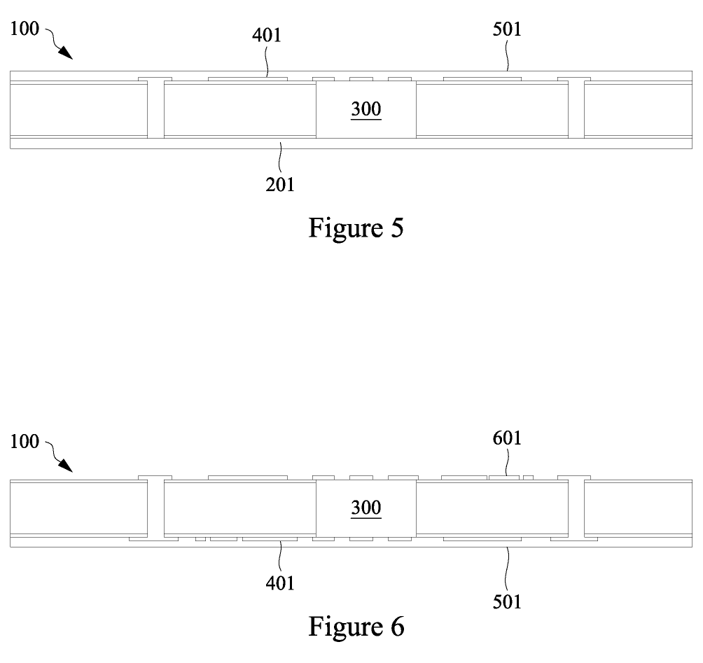

FIG. 5 illustrates a cross-sectional view of a formation of a first dielectric layer 501 over the exposed surface of the first core substrate 100 and over the first conductive traces 401. In some embodiments, the first dielectric layer 501 comprises a dielectric material, such as, silicon nitride, silicon oxide, phosphosilicate glass (PSG), borophosphosilicate glass (BPSG), or the like. In some embodiments, the first dielectric layer 501 may be formed of a polymer, which may be a photo-sensitive material such as PBO, polyimide, BCB, or the like, that may be patterned using a lithography mask. The first dielectric layer 501 may be formed by spin coating, lamination, chemical vapor deposition (CVD), the like, or a combination thereof. However, any suitable material or method of formation may be utilized in the formation of the first dielectric layer 501. Further, in some embodiments, a planarization process is performed to give the first dielectric layer 501 a planar outer surface.

FIG. 6 illustrates a cross-sectional view of a removal of the film tape 201 and a formation of second conductive traces 601 over an exposed surface of the first core substrate 100 and the first semiconductor component 300 embedded within the first core substrate 100. In an embodiment, the first core substrate 100 is flipped over, and the film tape 201 is removed. In an embodiment, the film tape 201 may be removed by a mechanical process, such as a grinding process, a chemical process, such as an etch, or a combination thereof, such as a CMP. However, any suitable method may be utilized in the removal of the film tape 201. Once the film tape 201 has been removed, the second conductive traces 601 may be formed and patterned in a similar manner as discussed above with respect to the formation of the first conductive traces 401. However, any suitable method or material may be utilized in the formation of the second conductive traces 601. Further, FIG. 6 is illustrated as the first semiconductor component 300 having contact pads (e.g., the first conductive traces 401 and the second conductive traces 601) formed on both sides of the first semiconductor component 300, resulting in the first semiconductor component 300 having double-sided pads, this is merely illustrative. In an embodiment, the second conductive traces 601 or the first conductive traces 401 may either serve as the contact pads to the first semiconductor component 300 such that the first semiconductor component 300 has single-side pads.

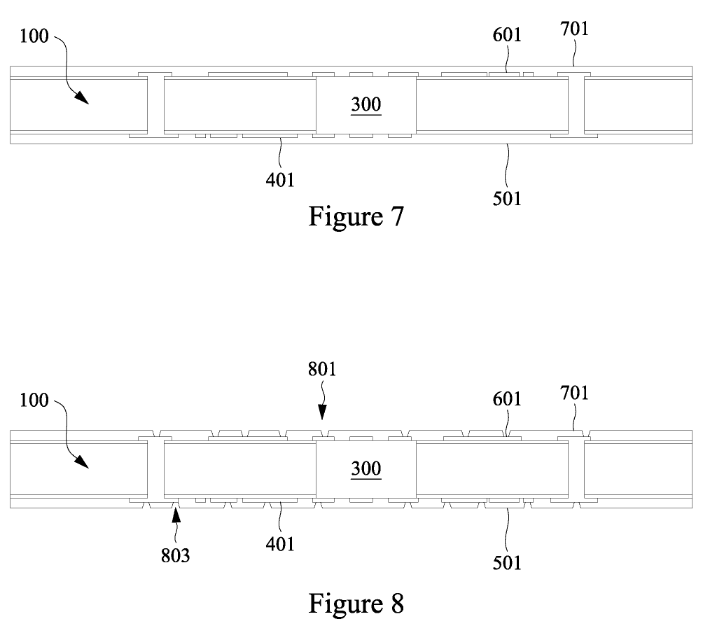

FIG. 7 illustrates a cross-sectional view of a formation of a second dielectric layer 701 over the exposed surfaces of the first core substrate 100 and over the second conductive traces 601. In some embodiments, the second dielectric layer 701 may be formed in a similar manner and of similar materials as discussed above with respect to the formation of the first dielectric layer 501. However, any suitable method or material may be utilized in the formation of the second dielectric layer 701.

FIG. 8 illustrates a cross-sectional view of a formation of second openings 801 formed in the second dielectric layer 701 and third openings 803 formed in the first dielectric layer 501. In some embodiments, the second openings 801 and the third openings 803 may be formed by a laser drilling process into the corresponding dielectric layer, the second dielectric layer 701 or the first dielectric layer 501. In some embodiments, the second openings 801 and the third openings 803 are formed by etching the first dielectric layer 501 and the second dielectric layer 701 with a suitable etching process (e.g., anisotropic reactive ion etching) through a patterned photoresist mask. In some embodiments in which either the first dielectric layer 501 and the second dielectric layer 701 are formed of a photo-sensitive material the second openings 801 and the third openings 803 may be formed in the corresponding dielectric layer by exposing the first dielectric layer 501 or the second dielectric layer 701 to light. The formation of the second openings 801 exposes portions of the first conductive traces 401 and the formation of the third openings 803 exposes portions of the second conductive traces 601. However, any suitable process may be utilized to form the second openings 801 and the third openings 803 in the corresponding dielectric layers, the second dielectric layer 701, the first dielectric layer 501. Although not illustrated, the formation of the second openings 801 and the third openings 803 may include multiple steps of flipping and placing the structure on a tape or carrier.

FIG. 9 illustrates a cross-sectional view of a formation of a first metallization pattern 901 in the second openings 801 and over the second dielectric layer 701 and a second metallization pattern 903 in the third openings 803 and over the first dielectric layer 501. In an embodiment, the first metallization pattern 901 may be formed in a similar manner and with similar materials as discussed with respect to the first conductive traces 401 The first metallization pattern 901 includes conductive traces formed along the top surface of the second dielectric layer 701 and conductive vias through the second dielectric layer 701 in the second openings 801. The vias connect the conductive traces of the first metallization pattern 901 electrically and physically to the metal pattern directly below the second dielectric layer 701 (e.g., the second conductive traces 601). In some embodiments, the conductive vias of the first metallization pattern 901 are blind vias that electrically connect to the first semiconductor component 300. However, any suitable processes and materials may be utilized in the formation of the first metallization pattern 901.

Further, the second metallization pattern 903 may be formed in a similar manner and with similar materials as discussed with respect to the first metallization pattern 901, with the second metallization pattern 903 being formed in the third openings 803 and over the first dielectric layer 501. However, any suitable processes and materials may be utilized in the formation of the second metallization pattern 903. It should be noted, that while structures discussed are being formed on both sides of the first core substrate 100, this may be achieved through use of support substrates, attachment films, or the like, (not illustrated) and similar approaches may be utilized in the formation of subsequent structures throughout this discussion.

The method of forming the first dielectric layer 501, the second dielectric layer 701, the conductive traces and vias of the first metallization pattern 901, and the conductive traces and vias of the second metallization pattern 903 is described as an example. It should be appreciated that the processes for forming these dielectric layers and metallization patterns may be varied based on the specifications of the design, e.g., the desired minimum dimensions of the patterns. For example, in some embodiments, a damascene process (e.g., a single or a dual damascene process) may be utilized. Further, the first core substrate 100 with the first semiconductor component 300 embedded within along with the first dielectric layer 501, the second dielectric layer 701, the first metallization pattern 901, and the second metallization pattern 903 may collectively be referred to as a first substrate layer 900.

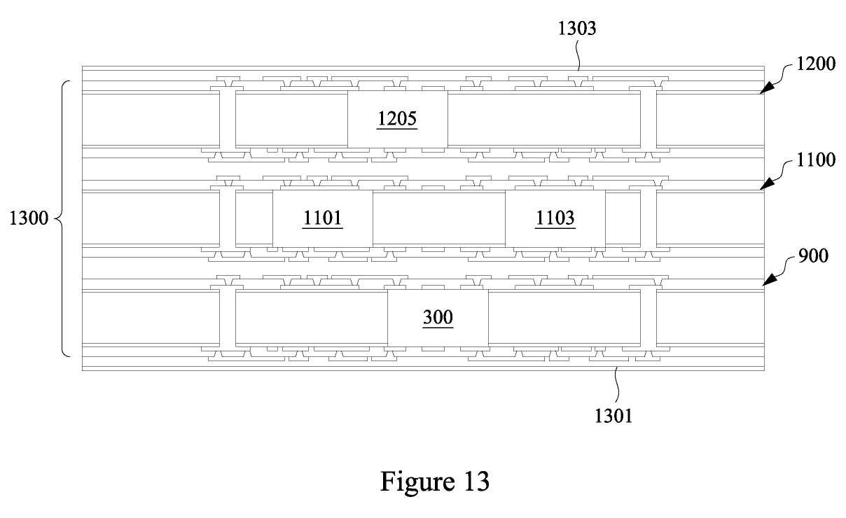

FIGS. 10 through 13 illustrate cross-sectional views of various steps in forming a multi-core substrate 1300 (see FIG. 13) through attaching the first substrate layer 900 to the second substrate layer 1100 (see FIG. 11) and the second substrate layer 1100 to the third substrate layer 1200 (see FIG. 12). In an embodiment, the various substrate layers used in the forming the multi-core substrate 1300 may be adhered to each other by placing the layers in contact with a resin film (e.g., a first resin film 1001, see FIG. 10) and subsequently curing the resin film such that as the resin film cures the substrate layers become adhered to one another.

FIG. 10 illustrates a cross-sectional view of a formation of a first resin film 1001 over the exposed surface of the second dielectric layer 701 and over the first metallization pattern 901. In an embodiment, the first resin film 1001 may be a polymer resin film, an epoxy resin film, a dielectric material, or the like. In an embodiment, the first resin film 1001 may be applied using a process such as a spin-on coating process, a dip coating method, an air-knife coating method, a curtain coating method, a wire-bar coating method, a gravure coating method, a lamination method, an extrusion coating method, combinations of these, or the like. In an embodiment, the first resin film 1001 may be applied in liquid or semi-liquid form and then subsequently cured. However, any suitable material and method of formation may be utilized in the formation of the first resin film 1001. The first resin film 1001 may be formed to a second thickness TH2. In an embodiment, the second thickness TH2 may be in a range from 50 µm to 1,400 µm. If the first resin film 1001 is formed to a thickness less than the second thickness TH2 then subsequent bonding of structures (e.g., a second substrate layer 1100, see FIG. 11) to the first resin film 1001 may not be adequate. If the first resin film 1001 is formed to a thickness greater than the second thickness TH2 then the first resin film 1001 may not be able to adequately cure during subsequent bonding processes.

FIG. 11 illustrates a cross-sectional view of an attachment of the first substrate layer 900 and the second substrate layer 1100. In an embodiment, the second substrate layer 1100 may be formed in a manner similar to the manner discussed above with respect to the formation of the first substrate layer 900. Further, the second substrate layer 1100 is illustrated with having two semiconductor components, a second semiconductor component 1101 and a third semiconductor component 1103 embedded within a second core substrate 1105, however, this is merely illustrative and any number of semiconductor components may be embedded within the respective core substrates of the various substrate layers (e.g., the first substrate layer 900 and the second substrate layer 1100). Additionally, the second core substrate 1105 may be formed to a third thickness TH3 in order to facilitate the embedding of the second semiconductor component 1101 and the third semiconductor component 1103. The third thickness TH3 has the same range as the first thickness TH1. In an embodiment, the third thickness TH3 may be greater than the first thickness TH1. In an embodiment, the third thickness TH3 may be greater than TH1.

Further, in an embodiment, the second substrate layer 1100 is attached to the first substrate layer 900 through an attachment process 1150. In an embodiment, the attachment process 1150 utilizes the first resin film to adhere the second substrate layer 1100 to the first substrate layer 900 by placing a bottom surface of the second substrate layer into contact with a top surface of the first resin film 1001. The first resin film 1001 may then be cured in order to harden the material of the first resin film 1001 and adhere the first substrate layer 900 to the second substrate layer 1100. In an embodiment the attachment process 1150 may be a furnace curing process, whereby a structure having the second substrate layer 1100 over the first resin film 1001 is placed into a furnace and is surrounded by an inert environment. In an embodiment the inert environment may be an inert gas such as argon, neon, or the like, or else may be an environment which is non-reactive to the exposed surfaces. Once the structure is within the furnace, the furnace will use heating elements to raise the temperature of the inert environment and, thus raise the temperature of the first resin film 1001 and other structures.

In an embodiment, the attachment process 1150 may raise the temperature to a curing temperature range of 40 C° to 350 C°. If the temperature is raised above the first temperature range then the first resin film 1001 as well as other structures may be damaged. If the temperature is below the first temperature range then the first resin film 1001 may not adequately cure to adhere the first substrate layer 900 to the second substrate layer 1100. Additionally, the attachment process 1150 may be performed for an adequate amount of time to ensure the resin film 1001 hardens enough to sufficiently adhere the first core substrate 100 to the second substrate layer 1100 without causing damage to the resin film 1001 or either the first core substrate 100 or the second substrate layer 1100.

Additionally, while a furnace curing process is described above as one embodiment of the attachment process 1150, this is intended to be illustrative and is not intended to be limiting in any fashion. Rather, any suitable attachment process, such as rapid thermal cures, flash anneals, laser anneals, combinations of these, or the like, may also be used. Any suitable method of curing may be utilized, and all such methods are fully intended to be included within the scope of the embodiments.

FIG. 12 illustrates a cross-sectional view of an attachment of a third substrate layer 1200 to the second substrate layer 1100 following a formation of a second resin film 1201 over the second substrate layer 1100. In an embodiment the second resin film 1201 may be formed of a similar material as discussed with respect to the first resin film 1001 and may be formed in a similar manner over the second substrate layer 1100 in a similar manner as discussed above with respect to the formation of the first resin film 1001 of the first substrate layer 900. However, any suitable material and method of formation may be utilized in the formation of the second resin film 1201.

Additionally, the third substrate layer 1200 may be formed in a similar manner to the manner discussed above with respect to the formation of the first substrate layer 900 and the second substrate layer 1100. Further, the third substrate layer 1200 may have any number of semiconductor components embedded within the respective core substrate. Additionally, a third core substrate 1203 of the third substrate layer 1200 may be formed to a fourth thickness TH4 in order to facilitate the embedding of a fourth semiconductor component 1205. The fourth thickness TH4 has the same thickness range as the first thickness TH1. In an embodiment, the fourth thickness TH4 may be the same or different than the first thickness TH1 or the third thickness TH3.

Further, in an embodiment, the attachment of the third substrate layer 1200 to the second substrate layer 1100 may be attached in a similar manner as discussed above with respect to the attachment of the first substrate layer 900 to the second substrate layer 1100, for example, after placing the third substrate layer on the second resin film 1201, the second resin film 1201 may be cured in a similar manner as the first resin film 1001. Following the attachment of the third substrate layer 1200 to the second substrate layer 1100 the subsequent structure may be referred to as a multi-core substrate 1300 (illustrated in FIG. 13). It should be noted that while FIG. 10 through FIG. 12 illustrate the formation of a multi-core substrate 1300 comprising of three individual substrate layers having core substrates with embedded semiconductor components, this is merely illustrative and any number of substrate layers having core substrates with embedded semiconductor components may be adhered in the formation of the multi-core substrate 1300.

FIG. 13 illustrates a cross-sectional view of a formation of a third dielectric layer 1301 and a fourth dielectric layer 1303 on opposing sides of the multi-core substrate 1300. In an embodiment, both the third dielectric layer 1301 and the fourth dielectric layer 1303 may be formed in a similar manner and from similar materials as discussed above with respect to the first dielectric layer 501 with the third dielectric layer 1301 being formed over an exposed side of the first substrate layer 900 and the fourth dielectric layer 1303 being formed over an exposed side of the third substrate layer 1200. However, any suitable material and process may be utilized in the formation of the third dielectric layer 1301 and the fourth dielectric layer 1303.

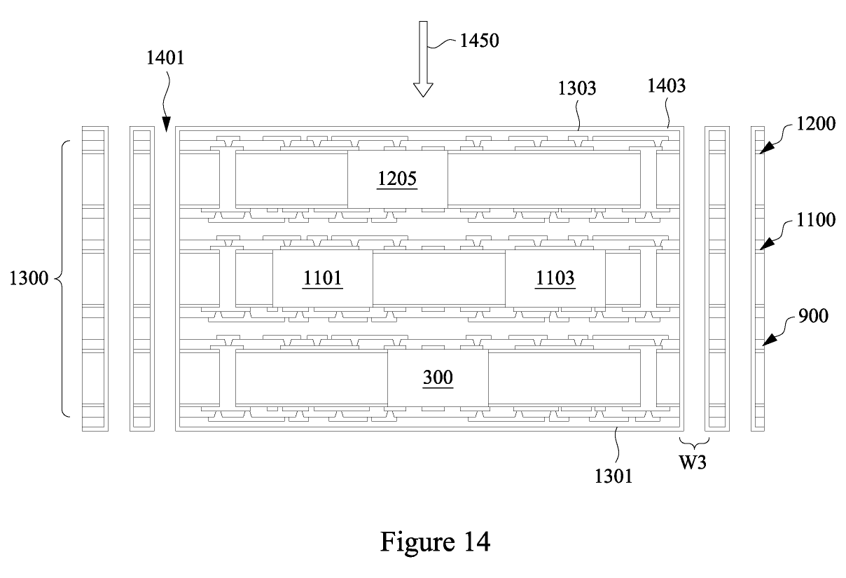

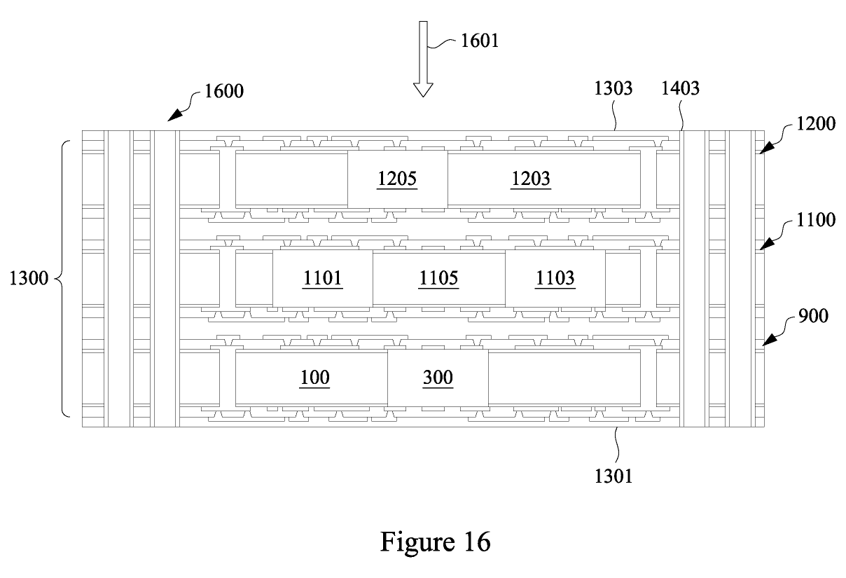

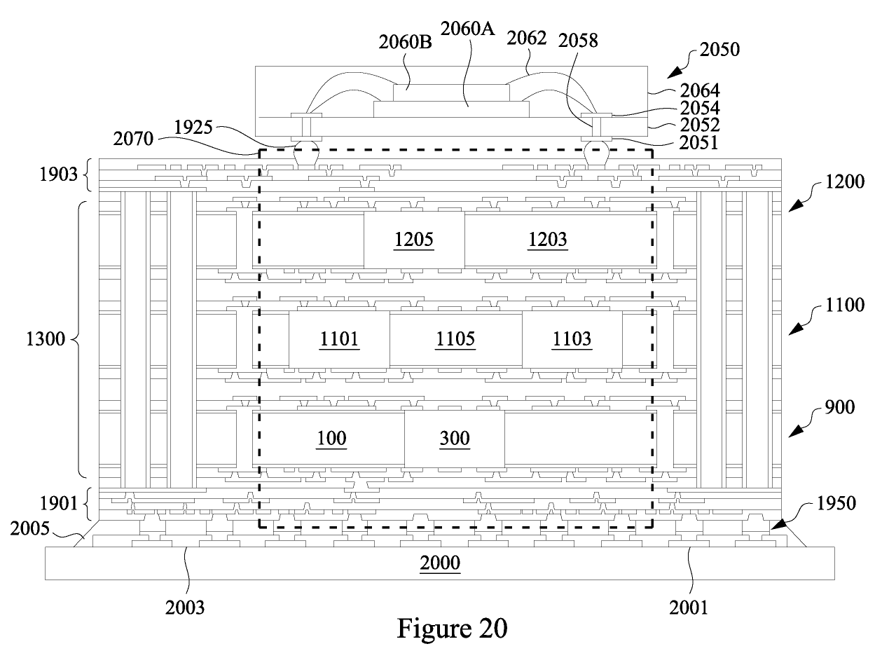

FIGS. 14 through 16 illustrate cross-sectional views of various steps in forming second through vias 1600 (see FIG. 16) through the multi-core substrate 1300. In an embodiment, the second through vias 1600 are plated through hole vias. Further, in an embodiment, the second through vias 1600 are formed on a perimeter of a region (e.g., a die shadow 2070, see FIG. 20) in which the various semiconductor components are embedded within the various core substrates of the multi-core substrate 1300 within the region.

FIG. 14 illustrates a cross-sectional view of an intermediate step in forming the second through vias 1600 (see FIG. 16). In an embodiment, fourth openings 1401 for the through vias 1600 may be formed using a drilling process, photolithography, a laser process, or other methods. In an embodiment, the fourth openings 1401 are formed outside the region containing the embedded semiconductor components within the multi-core substrate 1300. In an embodiment, the fourth openings 1401 may have a rectangular, circular, or other shape in a top-down view. In an embodiment, the fourth openings 1401 may be formed to a third width W3 to facilitate formation of the conductive material within the fourth openings 1401 (e.g., a second conductive layer 1403). The third width W3 may be in the range of the second width W2. In some embodiments, the third width W3 may be greater than the second width W2 to accommodate a formation of a larger through via through the multi-core substrate 1300.

Following the formation of the fourth openings 1401, a second surface preparation process 1450 may be performed. The second surface preparation process 1450 may include cleaning the exposed surfaces of the multi-core substrate 1300 with one or more cleaning solutions (e.g., sulfuric acid, chromic acid, neutralizing alkaline solution, water rinse or the like) to remove or reduce soil, oils, and/or native oxide films. A desmear process may be performed to clean the area near the fourth openings 1401, which may have been smeared with the material of the various materials of the multi-core substrate 1300 that were removed to form the fourth openings 1401. The desmearing may be accomplished mechanically (e.g., blasting with a fine abrasive in a wet slurry), chemically (e.g., rinsing with a combination of organic solvents, permanganate or the like), or by a combination of mechanical and chemical desmearing. Following cleaning, treatment with a chemical conditioner, which facilitates adsorption of an activator used during subsequent electroless plating, may be used.

Following the formation of the fourth openings 1401 through the multi-core substrate 1300, the exposed surfaces of the multi-core substrate 1300 including sidewalls of the fourth openings 1401 are lined with the second conductive layer 1403. In an embodiment, the second conductive layer 1403 may comprise of a conductive material such as copper, a copper alloy, or other conductors, and may include a barrier layer (not separately illustrated), a liner (not separately illustrated), and a seed layer (not separately illustrated). In an embodiment, the second conductive layer 1403 may be formed in part by using a metal electroless plating technique. However, any suitable material and formation method may be utilized in the formation of the second conductive layer 1403. It should be noted that the second conductive layer 1403 is illustrated as completely covering the top and bottom surfaces of the multi-core substrate 1300, this is merely illustrative and the formation of the second conductive layer 1403 may include forming a patterned mask layer (not separately illustrated) and selectively depositing conductive materials.

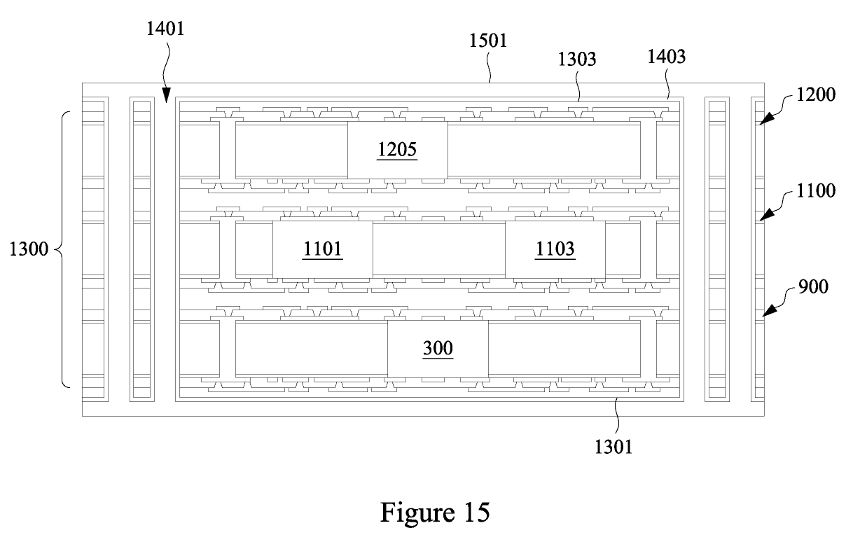

FIG. 15 illustrates a cross-sectional view of a formation of a fill material 1501 for the second through vias 1600. In some embodiments, the second through vias 1600 are hollow conductive through vias having centers that are filled with the fill material 1501 being an insulating material. In other embodiments, the fill material 1501 may be a conductive material such as copper, copper alloy, nickel, nickel alloy, aluminum, aluminum alloy, or other conductors. The fill material 1501 may be plated or deposited over the second conductive layer 1403. In an embodiment, the fill material 1501 may be overfilled on either or both sides of the multi-core substrate 1300. However, any suitable material and formation method may be utilized in the formation of the fill material 1501 within the fourth openings 1401 over the second conductive layer 1403.

FIG. 16 illustrates a cross-sectional view of the formation of the second through vias 1600 following a planarization process 1601. In an embodiment, overfill of the fill material 1501 (and if present portions of the second conductive layer 1403 along the outer surfaces of the outer dielectric layers of the multi-core substrate 1300) may be removed through the planarization process. In an embodiment, the planarization process 1601 results in the opposing surfaces of the second through vias 1600 being coplanar with the respective outer dielectric layers of the multi-core substrate 1300 (the third dielectric layer 1301 and the fourth dielectric layer 1303). The planarization process 1601 may be, for example, a chemical-mechanical polish (CMP) process, a grinding process, an etching process, the like, or a combination thereof. However, any suitable planarization process may be utilized in the formation of the second through vias 1600.

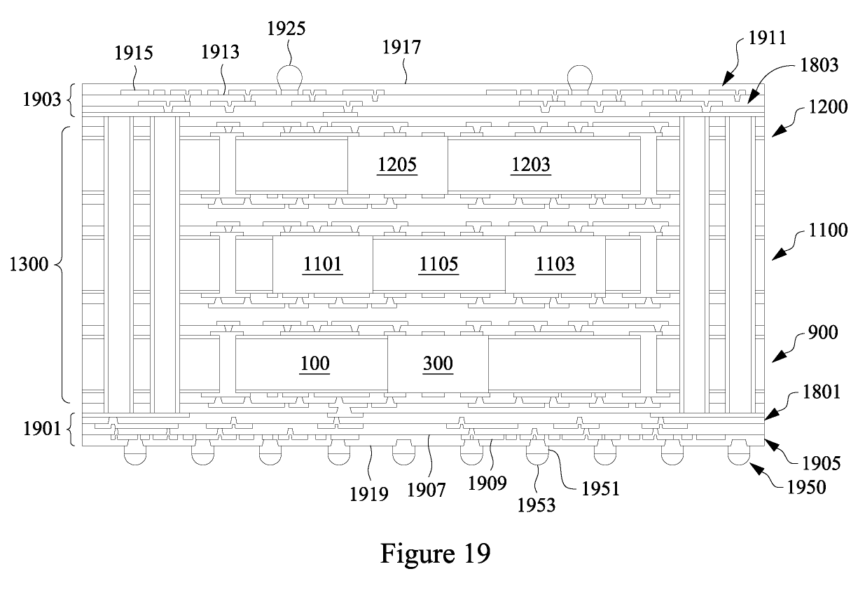

The second through vias 1600 provide vertical electrical connections from one side of the multi-core substrate 1300 to the other side of the multi-core substrate 1300 as well as vertical electrical connections between the various substrate layers (e.g., the first substrate layer 900, the second substrate layer 1100, the third substrate layer 1200, or the like) along with the embedded semiconductor components (e.g., the first semiconductor component 300, the second semiconductor component 1101, the third semiconductor component 1103, the fourth semiconductor component 1205, or the like) within the various core substrates (e.g., the first core substrate 100, the second core substrate 1105, the third core substrate 1203, or the like). For example, some of the second through vias 1600 are coupled between conductive features (e.g., first redistribution structure 1901, see FIG. 19) at one side of the multi-core substrate 1300 and conductive features (e.g., second redistribution structure 1903, see FIG. 19) at an opposite side of the multi-core substrate 1300. It should be noted that while two of the second through vias 1600 are illustrated on either side of the region containing the embedded semiconductor components within the multi-core substrate 1300, this is merely illustrative and any number of second through vias 1600 may be formed to provide adequate connection throughout and across the multi-core substrate 1300.

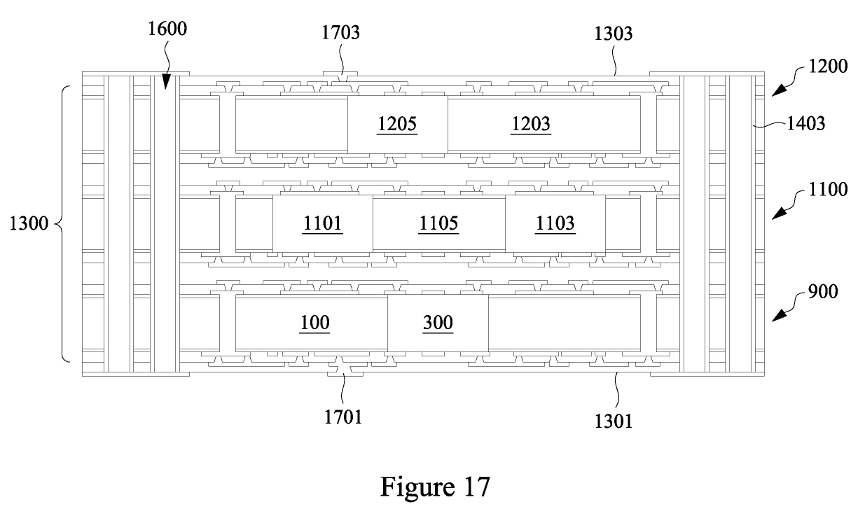

FIG. 17 illustrates a cross-sectional view of a formation of a third metallization pattern 1701 and a fourth metallization pattern 1703 on opposing sides of the multi-core substrate 1300. In an embodiment, the third metallization pattern 1701 and the fourth metallization pattern 1703 are formed in a similar manner and of similar materials as the second metallization pattern 903. The formation of the third metallization pattern 1701 may include forming vias in openings formed in the third dielectric layer 1301 to form electrical connections with conductive features of metallization patterns in the first substrate layer 900 and conductive lines of the third metallization pattern 1701 may be formed over the vias and over an exposed surface of the second through via 1600 forming an electrical connection with the second through via 1600 (e.g., forming an electrical connection through the second conductive layer 1403). The formation of the fourth metallization pattern 1703 may include forming vias in openings formed in the fourth dielectric layer 1303 to form electrical connections with conductive features of metallization patterns in the third substrate layer 1200 and conductive lines of the fourth metallization pattern 1703 may be formed over the vias and over an exposed surface of the second through via 1600 forming an electrical connection with the second through via 1600 (e.g., forming an electrical connection through the second conductive layer 1403).

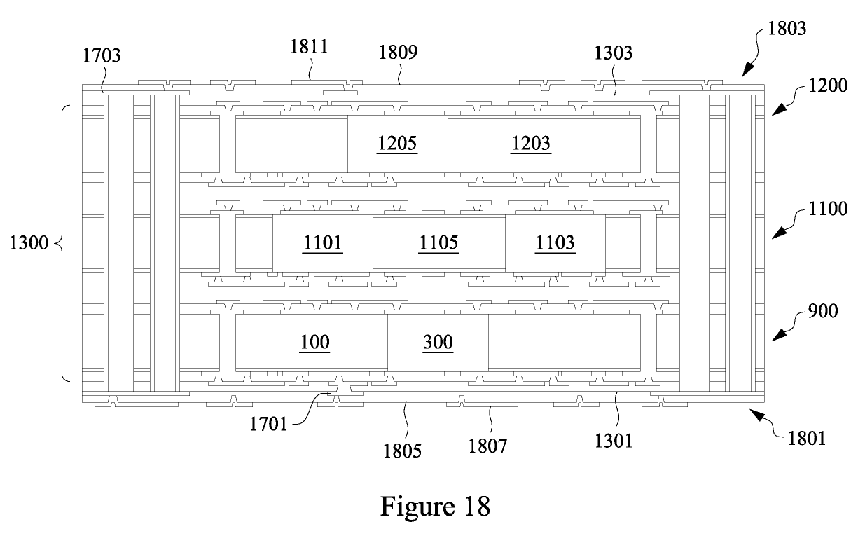

In some embodiments, the structure of FIG. 18 may be utilized as a probe card in semiconductor device testing, such as a probe card for testing for known good dies. For example, probe pins or needles (not shown) may be formed on one or both sides of the structure of FIG. 18 to facilitate the testing of devices. By being able to embed multiple components into the integrated substrate, the electrical design requirement of the probe card can be matched (e.g., different capacitors and inductors in same integrated substrate). Further, the multiple embedded components (e.g., capacitors) improve the probe card's power integrity and signal integrity to enable it to meet the test requirements of high-end devices.

FIG. 18 illustrates a cross-sectional view of a formation of a first redistribution layer 1801 over the third metallization pattern 1701 and of a second redistribution layer 1803 over the fourth metallization pattern 1703. In an embodiment, the first redistribution layer 1801 includes a fifth dielectric layer 1805 and a fifth metallization pattern 1807. In some embodiments, the fifth dielectric layer 1805 is formed of a photo-sensitive material such as PBO, polyimide, BCB, or the like, which may be patterned using a lithography mask. The fifth dielectric layer 1805 may be formed by spin coating, lamination, CVD, the like, or a combination thereof. The fifth dielectric layer 1805 is then patterned. The patterning forms openings exposing portions the third metallization pattern 1701. The patterning may be by an acceptable process, such as by exposing and developing the fifth dielectric layer 1805 to light when the fifth dielectric layer 1805 is a photo-sensitive material or by etching using, for example, an anisotropic etch.

The fifth metallization pattern 1807 may then be formed. The fifth metallization pattern 1807 may include conductive elements extending along the major surface of the fifth dielectric layer 1805 and extending through the fifth dielectric layer 1805 to physically and electrically couple to the third metallization pattern 1701. As an example to form the fifth metallization pattern 1807, a seed layer (not separately illustrated) is formed over the fifth dielectric layer 1805 and in the openings extending through the fifth dielectric layer 1805. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using, for example, PVD or the like. A photoresist is then formed and patterned on the seed layer. The photoresist may be formed by spin coating or the like and may be exposed to light for patterning. The pattern of the photoresist corresponds to the fifth metallization pattern 1807. The patterning forms openings through the photoresist to expose the seed layer. A conductive material is then formed in the openings of the photoresist and on the exposed portions of the seed layer. The conductive material may be formed by plating, such as electroplating or electroless plating, or the like. The conductive material may comprise a metal, like copper, titanium, tungsten, aluminum, or the like. The combination of the conductive material and underlying portions of the seed layer form the fifth metallization pattern 1807. The photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching.

In an embodiment, the second redistribution layer 1803 may include a sixth dielectric layer 1809 and a sixth metallization pattern 1811. The sixth dielectric layer 1809 may be formed of similar materials and in a similar manner as discussed above with respect to the fifth dielectric layer 1805 and the sixth metallization pattern 1811 may be formed in a similar manner as discussed above with respect to the fifth metallization pattern 1807. However, any suitable materials or methods may be utilized in the formation of both the first redistribution layer 1801 and the second redistribution layer 1803.

FIG. 19 illustrates a cross-sectional view of a formation of the first redistribution structure 1901 and of the second redistribution structure 1903. In an embodiment, the first redistribution structure 1901 may include the first redistribution layer 1801 and a third redistribution layer 1905, the third redistribution layer 1905 having a seventh dielectric layer 1907 and a seventh metallization pattern 1909. In an embodiment, the second redistribution structure 1903 may include the second redistribution layer 1803 and a fourth redistribution layer 1911, the fourth redistribution layer 1911 having an eighth dielectric layer 1913 and an eighth metallization pattern 1915. In an embodiment, the third redistribution layer 1905 and the fourth redistribution layer 1911 may be formed in a similar manner and with similar materials as the first redistribution layer 1801. Further it should be noted that while each redistribution structure (e.g., the first redistribution structure 1901 and the second redistribution structure 1903) are illustrated as each having two redistribution layers, this is merely illustrative and any number of redistribution layers may be formed in forming the redistribution structures.

Further, following the formation of the first redistribution structure 1901 and the second redistribution structure 1903, first external connectors 1925 are formed in electrical connection with the second redistribution structure 1903 and second external connectors 1950 are formed in electrical connection with the first redistribution structure 1901. In some embodiments, the first external connectors 1925 are formed extending through a ninth dielectric layer 1917 to contact the eighth metallization pattern 1915. Openings are formed through the ninth dielectric layer 1917 to expose portions of the eighth metallization pattern 1915. The openings may be formed, for example, using laser drilling, etching, or the like. The first external connectors 1925 are formed in the openings. In some embodiments, the first external connectors 1925 comprise flux and are formed in a flux dipping process. In some embodiments, the first external connectors 1925 comprise a conductive paste such as solder paste, silver paste, or the like, and are dispensed in a printing process. In some embodiments, the second external connectors 1950 comprises forming under bump metallization (UBMs) 1951 and first conductive connectors 1953 The UBMs 1951 have bump portions on and extending along the major surface of a tenth dielectric layer 1919, and have via portions extending through the tenth dielectric layer 1919 to physically and electrically couple the seventh metallization pattern 1909. The UBMs 1951 may be formed of the same material as the seventh metallization pattern 1909. In some embodiments, the UBMs 1951 have a different size than the metallization patterns (e.g., the seventh metallization pattern 1909). In some embodiments, first conductive connectors 1953 are formed on the UBMs 1951. The first conductive connectors 1953 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The first conductive connectors 1953 may include a conductive material such as solder, copper, aluminum, gold, nickel, silver, palladium, tin, the like, or a combination thereof. In some embodiments, the first conductive connectors 1953 are formed by initially forming a layer of solder through evaporation, electroplating, printing, solder transfer, ball placement, or the like. Once a layer of solder has been formed on the structure, a reflow may be performed in order to shape the material into the desired bump shapes. In another embodiment, the first conductive connectors 1953 comprise metal pillars (such as a copper pillar) formed by a sputtering, printing, electro plating, electroless plating, CVD, or the like. The metal pillars may be solder free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof and may be formed by a plating process.

FIG. 20 illustrates a cross-sectional view of an attachment of the multi-core substrate 1300 to a package substrate 2000 and an attachment of a semiconductor device 2050 to the multi-core substrate 1300. In an embodiment, the multi-core substrate 1300 may be attached to the package substrate 2000 by bonding the second external connectors 1950 to first bond pads 2001 of the package substrate. In an embodiment, the semiconductor device 2050 may be attached to the multi-core substrate 1300 by bonding the first external connectors 1925 to second bond pads 2051 of the semiconductor device 2050.

In an embodiment, the package substrate 2000 may be a printed circuit board (PCB) or the like. The package substrate 2000 may include one or more dielectric layers and electrically conductive features, such as conductive lines and vias (not separately illustrated). In some embodiments, the package substrate 2000 may include through-vias, active devices, passive devices, and the like (not separately illustrated). The package substrate 2000 may further include conductive pads formed at the upper and lower surfaces of the package substrate 2000 (e.g., the first bond pads 2001). In an embodiment, a passivation layer 2003 is formed over the first bond pads 2001, openings may be formed in the passivation layer 2003 to expose the first bond pads 2001 such that the first conductive connectors 1953 may be placed in contact with the first bond pads 2001 and be reflowed. Further, in an embodiment, an underfill material 2005 may be formed between the multi-core substrate 1300 and the package substrate 2000. The underfill material 2005 may reduce stress and protect the joints resulting from the reflowing of the first conductive connectors 1953 to the first bond pads 2001. The underfill material 2005 may be formed by a capillary flow process after the multi-core substrate 1300 and the package substrate 2000 are attached.

In an embodiment, the semiconductor device 2050 is coupled to the multi-core substrate 1300. The semiconductor device 2050 include, for example, a substrate 2052 and one or more stacked dies 2060 coupled to the substrate 2052. Although one set of stacked dies 2060 is illustrated, in other embodiments, a plurality of stacked dies 2060 (each having one or more stacked dies) may be disposed side-by-side coupled to a same surface of the substrate 2052. The substrate 2052 may be made of a semiconductor material such as silicon, germanium, diamond, or the like. In some embodiments, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the substrate 2052 may be a silicon-on-insulator (SOI) substrate. Generally, an SOI substrate includes a layer of a semiconductor material such as epitaxial silicon, germanium, silicon germanium, SOI, silicon germanium on insulator (SGOI), or combinations thereof. The substrate 2052 is, in one alternative embodiment, based on an insulating core such as a fiberglass reinforced resin core. One example core material is fiberglass resin such as FR4. Alternatives for the core material include bismaleimide-triazine (BT) resin, or alternatively, other printed circuit board (PCB) materials or films. Build up films such as Ajinomoto build-up film (ABF) or other laminates may be used for substrate 2052.

The substrate 2052 may include active and passive devices (not shown). A wide variety of devices such as transistors, capacitors, resistors, combinations of these, and the like may be used to generate the structural and functional requirements of the design for the semiconductor device 2050. The devices may be formed using any suitable methods.

The substrate 2052 may also include metallization layers (not shown) and conductive vias 2058. The metallization layers may be formed over the active and passive devices and are designed to connect the various devices to form functional circuitry. The metallization layers may be formed of alternating layers of dielectric (e.g.¸ low-k dielectric material) and conductive material (e.g., copper) with vias interconnecting the layers of conductive material and may be formed through any suitable process (such as deposition, damascene, dual damascene, or the like). In some embodiments, the substrate 2052 is substantially free of active and passive devices.

The substrate 2052 may have third bond pads 2054 on a first side of the substrate 2052 to couple to the stacked dies 2060, and the second bond pads 2051 on a second side of the substrate 2052, the second side being opposite the first side of the substrate 2052, to couple to the first external connectors 1925. In some embodiments, the third bond pads 2054 and the second bond pads 2051 are formed by forming recesses (not shown) into dielectric layers (not shown) on the first and second sides of the substrate 2052. The recesses may be formed to allow the third bond pads 2054 and the second bond pads 2051 to be embedded into the dielectric layers. In other embodiments, the recesses are omitted as the third bond pads 2054 and the second bond pads 2051 may be formed on the dielectric layer. In some embodiments, the third bond pads 2054 and the second bond pads 2051 include a thin seed layer (not shown) made of copper, titanium, nickel, gold, palladium, the like, or a combination thereof. The conductive material of the third bond pads 2054 and the second bond pads 2051 may be deposited over the thin seed layer. The conductive material may be formed by an electro-chemical plating process, an electroless plating process, CVD, atomic layer deposition (ALD), PVD, the like, or a combination thereof. In an embodiment, the conductive material of the third bond pads 2054 and the second bond pads 2051 is copper, tungsten, aluminum, silver, gold, the like, or a combination thereof.

In some embodiments, the third bond pads 2054 and the second bond pads 2051 are UBMs that include three layers of conductive materials, such as a layer of titanium, a layer of copper, and a layer of nickel. Other arrangements of materials and layers, such as an arrangement of chrome/chrome-copper alloy/copper/gold, an arrangement of titanium/titanium tungsten/copper, or an arrangement of copper/nickel/gold, may be utilized for the formation of the third bond pads 2054 and the second bond pads 2051. Any suitable materials or layers of material that may be used for the third bond pads 2054 and second bond pads 2051 are fully intended to be included within the scope of the current application. In some embodiments, the conductive vias 2058 extend through the substrate 2052 and couple at least one of the third bond pads 2054 to at least one of the second bond pads 2051.

In the illustrated embodiment, the stacked dies 2060 are coupled to the substrate 2052 by wire bonds 2062, although other connections may be used, such as conductive bumps. In an embodiment, the stacked dies 2060 are stacked memory dies. For example, the stacked dies 2060 may be memory dies such as low-power (LP) double data rate (DDR) memory modules, such as LPDDR1, LPDDR2, LPDDR3, LPDDR4, or the like memory modules.

The stacked dies 2060 and the wire bonds 2062 may be encapsulated by a molding material 2064. The molding material 2064 may be molded on the stacked dies 2060 and the wire bonds 2062, for example, using compression molding. In some embodiments, the molding material 2064 is a molding compound, a polymer, an epoxy, silicon oxide filler material, the like, or a combination thereof. A curing process may be performed to cure the molding material 2064; the curing process may be a thermal curing, a UV curing, the like, or a combination thereof.

In some embodiments, the stacked dies 2060 and the wire bonds 2062 are buried in the molding material 2064, and after the curing of the molding material 2064, a planarization step, such as a grinding, is performed to remove excess portions of the molding material 2064 and provide a substantially planar surface for the semiconductor device 2050.

After the semiconductor device 2050 are formed, the semiconductor device 2050 are mechanically and electrically bonded to the multi-core substrate 1300 by way of the first external connectors 1925 and the second bond pads 2051. In some embodiments, a solder resist (not shown) is formed on the side of the substrate 2052 opposing the stacked dies 2060. The first external connectors 1925 may be disposed in openings in the solder resist to be electrically and mechanically coupled to conductive features (e.g., the second bond pads 2051) in the substrate 2052. The solder resist may be used to protect areas of the substrate 2052 from external damage.

In some embodiments, the first external connectors 1925 have an epoxy flux (not shown) formed thereon before they are reflowed with at least some of the epoxy portion of the epoxy flux remaining after the semiconductor device 2050 are attached to the multi-core substrate 1300.

In some embodiments, an underfill (not shown) is formed between the multi-core substrate 1300 and the semiconductor device 2050, surrounding the first external connectors 1925. The underfill may reduce stress and protect the joints resulting from the reflowing of the first external connectors 1925. The underfill may be formed by a capillary flow process after the semiconductor device 2050 are attached, or may be formed by a suitable deposition method before the semiconductor device 2050 are attached. In embodiments where the epoxy flux is formed, it may act as the underfill.

In an embodiment, the semiconductor device 2050 may include one or more dies, such as a logic die (e.g., central processing unit (CPU), graphics processing unit (GPU), system-on-a-chip (SoC), application processor (AP), microcontroller, or the like), a memory die (e.g., dynamic random access memory (DRAM) die, static random access memory (SRAM) die, or the like), a power management die (e.g., power management integrated circuit (PMIC) die), a radio frequency (RF) die, a sensor die, a micro-electro-mechanical-system (MEMS) die, a signal processing die (e.g., digital signal processing (DSP) die), a front-end die (e.g., analog front-end (AFE) dies), the like, or combinations thereof. In some embodiments, the semiconductor device 2050 may be an integrated circuit die.

FIG. 20 further illustrates a cross-sectional view of the die shadow 2070 as projected by the semiconductor device 2050 over the multi-core substrate 1300. In an embodiment, the die shadow represents a power domain correlating to the semiconductor device 2050. In an embodiment, the multi-core substrate 1300 has a component density within the die shadow 2070 of 4 or more semiconductor components per mm².

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

Embodiments may achieve advantages. By embedding various semiconductor components (e.g., the first semiconductor component 300) within various core substrates (e.g., the first core substrate 100) and bonding these various core substrates together (e.g., by the attachment process 1150) the high component density may be achieved which provides multiple advantages to the multi-core substrate 1300. The high component density within the multi-core substrate allows for the signal integrity to be maintained above 112 Gbps. Further, by having the component density within the multi-core substrate 1300 the power integrity across the multi-core substrate 1300 may be less than 1 mOhm at 100 MHz. Further, by forming through vias (e.g., the second through via 1600) and metallization patterns (e.g., the first metallization pattern 901) the high component density may be both electrically coupled internally between the various semiconductor components embedded within the multi-core substrate and externally across the multi-core substrate 1300 to other devices (e.g., the package substrate 2000 and the semiconductor device 2050) while maintaining adequate signal integrity and power integrity.

In accordance with some embodiments, a method of manufacturing a semiconductor device, the method including embedding a first semiconductor component in a first core substrate, embedding a second semiconductor component in a second core substrate, attaching the second core substrate to the first core substrate, wherein the attaching the second core substrate to the first core substrate forms a multi-layer core substrate, and forming a first plurality of through vias extending through the multi-layer core substrate, wherein the first plurality of through vias are electrically coupled to the first semiconductor component and to the second semiconductor component. In an embodiment, attaching the second core substrate to the first core substrate includes depositing a first resin film over the first core substrate, placing the second core substrate over the first resin film, and curing the first resin film. In an embodiment, further including forming a first redistribution layer on a first side of the first core substrate, wherein the first redistribution layer includes first conductive features, the first conductive features electrically coupling the first semiconductor component to one of the first plurality of through vias. In an embodiment, the forming the first plurality of through vias includes forming a plurality of through holes through the multi-layer core substrate, and plating a conductive material along sidewalls of the plurality of through holes. In an embodiment, further including bonding a semiconductor chip over a top surface of the multi-layer core substrate, wherein the semiconductor chip forms a die shadow power domain projection over the multi-layer core substrate, wherein the multi-layer core substrate has a component density within the die shadow power domain projection of 4 or more components per square millimeter. In an embodiment, further including embedding a third semiconductor component in a third core substrate, and attaching the third core substrate to the second core substrate on an opposite side of the second core substrate from the first core substrate, wherein the third core substrate is part of the multi-layer core substrate. In an embodiment, wherein the first core substrate has a first thickness and the second core substrate has a second thickness different from the first thickness.

In accordance with an embodiment, a device including a first semiconductor component embedded in a first core substrate, a first redistribution layer on a first side of the first core substrate, a second redistribution layer on a second side of the first core substrate opposite the first side, a first resin film over the second redistribution layer, a second semiconductor component embedded in a second core substrate, a third redistribution layer on a third side of the second core substrate, wherein the third redistribution layer is bonded to the second redistribution layer by the first resin film, a fourth redistribution layer on a fourth side of the second core substrate opposite the third side, and a through hole via extending through the first redistribution layer, the first core substrate, the second redistribution layer, the third redistribution layer, the second core substrate, and the fourth redistribution layer. In an embodiment, further including a second resin film over the fourth redistribution layer, a third semiconductor component embedded in a third core substrate, a fifth redistribution layer on a fifth side of the third core substrate, wherein the fifth redistribution layer is bonded to the fourth redistribution layer by the second resin film, and a sixth redistribution layer on a sixth side of the third core substrate opposite the fifth side. In an embodiment, further including a first redistribution build up structure over the sixth redistribution layer, a semiconductor chip bonded to the first redistribution build up structure opposite the sixth redistribution layer, a second redistribution build up structure under the first redistribution layer, and a substrate bonded to the second redistribution build up structure by external connectors. In an embodiment, the semiconductor chip has a die shadow projection through the first redistribution layer, the first core substrate, the second redistribution layer, the third redistribution layer, the second core substrate, the fourth redistribution layer, the fifth redistribution layer, the third core substrate and the sixth redistribution layer, wherein a component density exists within the die shadow projection, the component density being 4 or more components per square millimeter. In an embodiment, the first core substrate has a first thickness and the second core substrate has a second thickness different from the first thickness. In an embodiment, further including a fourth semiconductor component embedded within the second core substrate. In an embodiment, the first semiconductor component is an integrated passive device, an active chip, an integrated voltage regulator, or a multilayer ceramic capacitor.

In accordance with an embodiment, a method of manufacturing a semiconductor device includes forming a first substrate layer, wherein the first substrate layer includes a first semiconductor component embedded in a first core substrate, a first redistribution layer of the first substrate layer formed over the first core substrate, and a second redistribution layer of the first substrate layer formed on an opposite side of the first core substrate from the first redistribution layer of the first substrate layer, forming a second substrate layer, wherein the second substrate layer includes a second semiconductor component embedded in a second core substrate, a first redistribution layer of the second substrate layer formed over the second core substrate, and a second redistribution layer of the second substrate layer formed on an opposite side of the second core substrate from the first redistribution layer of the second substrate layer, bonding the second substrate layer to the first substrate layer, and forming a first through via extending through the first substrate layer and the second substrate layer, wherein the first through via is electrically coupled to the first semiconductor component. In an embodiment, further including forming a third substrate layer, wherein the third substrate layer includes a third semiconductor component embedded in a third core substrate, a first redistribution layer of the third substrate layer formed over the third core substrate, and a second redistribution layer of the third substrate layer formed on an opposite side of the third core substrate from the first redistribution layer of the third substrate layer, and bonding the third substrate layer to the second substrate layer on an opposite side from the first substrate layer. In an embodiment, further including forming a second through via extending through the first substrate layer, the second substrate layer, and the third substrate layer, wherein the second through via is electrically coupled to the second semiconductor component. In an embodiment, embedding the first semiconductor component in the first core substrate includes drilling a first hole through the first core substrate, attaching a polyimide film tape to one side of the first core substrate, performing a pick and place for the first semiconductor component onto the polyimide film tape in the first hole; and removing the polyimide film tape. In an embodiment, further including forming a local through core substrate via through the first core substrate. In an embodiment, wherein forming the first redistribution layer of the first substrate layer includes depositing a first dielectric material over the first core substrate through a film lamination process, curing the first dielectric material forming a first dielectric layer, forming a blind via opening through a laser process, and forming the blind via by plating a conductive material into the blind via opening.

In one general aspect, embodiments disclosed herein may include a device having a first semiconductor component embedded in a first core substrate. The device may also include a first redistribution layer on a first side of the first core substrate. The device may furthermore include a second redistribution layer on a second side of the first core substrate opposite the first side. The device may in addition include a first resin film over the second redistribution layer. The device may moreover include a second semiconductor component embedded in a second core substrate. The device may also include a third redistribution layer on a third side of the second core substrate, where the third redistribution layer is bonded to the second redistribution layer by the first resin film. Device may furthermore include a fourth redistribution layer on a fourth side of the second core substrate opposite the third side. The device may in addition include a through hole via extending through the first redistribution layer, the first core substrate, the second redistribution layer, the third redistribution layer, the second core substrate, and the fourth redistribution layer.

In another general aspect, embodiments disclosed herein may include a device having a first package component including a first core substrate, a first semiconductor device embedded in the first core substrate, and a first redistribution structure on a first side of the first core substrate. The device may furthermore include a second package component including a second core substrate, a second semiconductor device embedded in the second core substrate, and a second redistribution structure on a first side of the second core substrate. The device may moreover include a bond interface between the first package component and the second package component. The device may also include a through hole via extending through the first core substrate, the bond interface, and the second core substrate, the through hole via electrically coupled to the first semiconductor device and the second semiconductor device

In yet another general aspect embodiments disclosed herein may include a device having a multi-core substrate having a first semiconductor component embedded in a first core substrate, and a second semiconductor component embedded in a second core substrate, the second core substrate bonded to the first core substrate by a resin film. The device may in addition include a through hole via extending through the first core substrate and the second core substrate, the through hole via electrically coupled to the first semiconductor component and the second semiconductor component. The device may moreover include a package substrate bonded to a first side of the multi-core substrate by first external connectors. The device may also include a semiconductor device bonded to a second side of the multi-core substrate opposite the first side by second external connectors.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
a first semiconductor component embedded in a first core substrate;
a first redistribution layer on a first side of the first core substrate;
a second redistribution layer on a second side of the first core substrate opposite the first side;
a first resin film over the second redistribution layer;
a second semiconductor component embedded in a second core substrate;
a third redistribution layer on a third side of the second core substrate, wherein the third redistribution layer is bonded to the second redistribution layer by the first resin film;
a fourth redistribution layer on a fourth side of the second core substrate opposite the third side; and
a through hole via extending through the first redistribution layer, the first core substrate, the second redistribution layer, the third redistribution layer, the second core substrate, and the fourth redistribution layer.

2. The device of claim 1, further comprising:
a second resin film over the fourth redistribution layer;
a third semiconductor component embedded in a third core substrate;
a fifth redistribution layer on a fifth side of the third core substrate, wherein the fifth redistribution layer is bonded to the fourth redistribution layer by the second resin film; and
a sixth redistribution layer on a sixth side of the third core substrate opposite the fifth side.

3. The device of claim 2, further comprising:
a first redistribution build up structure over the sixth redistribution layer;
a semiconductor chip bonded to the first redistribution build up structure opposite the sixth redistribution layer;
a second redistribution build up structure under the first redistribution layer; and
a substrate bonded to the second redistribution build up structure by external connectors.

4. The device of claim 3, wherein the semiconductor chip has a die shadow projection through the first redistribution layer, the first core substrate, the second redistribution layer, the third redistribution layer, the second core substrate, the fourth redistribution layer, the fifth redistribution layer, the third core substrate and the sixth redistribution layer, wherein a component density exists within the die shadow projection, the component density being 4 or more components per square millimeter.

5. The device of claim 3, wherein a first end of the through hole via electrically contacts the first redistribution build up structure and a second end of the through hole via electrically contacts the second redistribution build up structure.

6. The device of claim 1, wherein the first core substrate has a first thickness and the second core substrate has a second thickness different from the first thickness.

7. The device of claim 1, further comprising a fourth semiconductor component embedded within the second core substrate.

8. The device of claim 1, wherein the first semiconductor component is an integrated passive device, an active chip, an integrated voltage regulator, or a multilayer ceramic capacitor.

9. The device of claim 1, wherein the first resin film has a thickness in a range of from 50 µm to 1400 µm.

10. The device of claim 1, wherein the first resin film comprises a material selected from the group consisting of a polymer resin film and an epoxy resin film.

11. A device comprising:
a first package component including:
a first core substrate,
a first semiconductor device embedded in the first core substrate, and
a first redistribution structure on a first side of the first core substrate;
a second package component including:
a second core substrate,
a second semiconductor device embedded in the second core substrate, and
a second redistribution structure on a first side of the second core substrate;
a bond interface between the first package component and the second package component; and
a through hole via extending through the first core substrate, the bond interface, and the second core substrate, the through hole via electrically coupled to the first semiconductor device and the second semiconductor device.

12. The device of claim 11, wherein the bond interface comprises a resin layer between the first redistribution structure and the second redistribution structure.

13. The device of claim 12, wherein the resin layer has a thickness in a range of from 50 µm to 1400 µm.

14. The device of claim 12 wherein a portion of the first redistribution structure, the second redistribution structure, or both the first redistribution structure and the second redistribution structure is embedded within the resin layer.

15. The device of claim 11, further comprising a third redistribution structure on a second side of the first core substrate opposite the first side of the first core substrate and a fourth redistribution structure on a second side of the second core substrate opposite the first side of the second core substrate.

16. A device comprising:
a multi-core substrate comprising:
a first semiconductor component embedded in a first core substrate;
a second semiconductor component embedded in a second core substrate, the second core substrate bonded to the first core substrate by a resin film; and
a through hole via extending through the first core substrate and the second core substrate, the through hole via electrically coupled to the first semiconductor component and the second semiconductor component;
a package substrate bonded to a first side of the multi-core substrate by first external connectors; and
a semiconductor device bonded to a second side of the multi-core substrate opposite the first side by second external connectors.

17. The device of claim 16, further comprising an underfill material between the package substrate and the multi-core substrate surrounding the first external connectors.

18. The device of claim 16, wherein the semiconductor device comprises a device substrate and a stacked die coupled to the device substrate by wire bonds, the stacked die and the wire bonds encapsulated by a molding material.

19. The device of claim 18, wherein a projection of the outer perimeter of the semiconductor device onto the multi-core substrate defines a die shadow region of the multi-core substrate, the die shadow region having a component density of 4 or more semiconductor components per square millimeter.

20. The device of claim 19, wherein the through hole via is located outside the die shadow region.
